(19) United States
(12) Patent Application Publication
(10) Pub. No.: US 2008/0149982 A1
(43) Pub. Date: Jun. 26, 2008

(54) CMOS TRANSISTOR

(75) Inventors: Reiner Jumpertz, Freising (DE); Klaus Schimpf, Freising (DE); Stefan Bogen, Nandistadt (DE)

Correspondence Address: TEXAS INSTRUMENTS INCORPORATED, P O BOX 655474, M/S 3999, DALLAS, TX, 75265, US

(73) Assignee: TEXAS INSTRUMENTS DEUTSCHLAND GMBH, Freising (DE)

(21) Appl. No.: 11/961,877

(22) Filed: Dec. 20, 2007

(30) Foreign Application Priority Data
Dec. 20, 2006 (DE) 10 2006 060342.7

(51) Int. Cl. H01L 27/07

(52) U.S. Cl. 257/306; 257/E27.03

(57) ABSTRACT

A CMOS transistor comprises a substrate with a gate electrode arranged thereon between source and drain regions. A capacitor is provided on the gate electrode and a voltage applied to the gate electrode is dropped across a stack, including the gate electrode and the capacitor.

This application claims priority from German Application No. 10 2006 060342.7, filed Dec. 20, 2006, the entirety of which is incorporated herein by reference.

### BACKGROUND

The invention generally relates to a CMOS transistor. More particularly, the invention relates to high density stacked transistor gates for high voltage applications.

Many products require integrated circuits having active components, for example CMOS transistors, with higher supply voltages than are currently achievable with the available technology. For example, a technology that is developed for a 3.3V application should provide a transistor that is capable of being used at 15V without process modification.

The problem of fabricating a CMOS transistor using a standard process, which has a drain that can withstand a higher voltage, has already been solved by the “drain extended” CMOS transistor. In this transistor, the length of the drain region is increased compared to that in a standard CMOS transistor. However, the problem of producing a CMOS transistor that can withstand a higher gate voltage, which can also be fabricated using a standard process, has not yet been solved.

### SUMMARY

The invention provides a CMOS transistor that can be produced with a standard process and withstands a higher gate voltage.

Thus, in one aspect the invention provides a CMOS transistor. The transistor comprises a substrate, upon which is arranged a gate electrode between source and drain regions. A capacitor is provided on the gate electrode. This means that the gate input voltage will be dropped across a stack including the gate electrode and the capacitor. In this way, a transistor is provided that allows a voltage to be applied to the gate terminal that is significantly higher than the breakdown voltage of the gate oxide itself, i.e., greater than 9V for a 75 Angstrom gate oxide. This transistor can easily be integrated in existing design libraries for integrated circuits implemented in CMOS technology; i.e., existing processes can be used to fabricate the transistor and it can be incorporated in large integrated circuits.

Preferably, the relative dimensions of the gate and the capacitor are configured so as to optimize the voltage drop over the capacitor. A higher voltage can then be applied to the gate because most of the supply voltage will be dropped over the capacitor provided on top of the gate electrode.

The transistor may also include a drain extension, which increases the drain-to-source breakdown voltage by reducing the electric field under the gate at the drain end of the transistor. This allows the transistor to operate at high drain voltages, as well as at higher gate voltages. A high resistive drain extension with lower dopant concentration than the drain region itself can be provided between the gate electrode and the drain. The drain current generates a voltage drop between the drain and the gate and the breakdown voltage between the drain and the source is significantly increased.

### BRIEF DESCRIPTION OF THE DRAWINGS

Further advantages and features of the invention will be apparent from the below description of preferred example embodiments, taken together with the accompanying drawings, wherein:

FIG. 1 (Prior Art) is a side cross-sectional view of a conventional drain-extended CMOS transistor;

FIG. 2 is a top view of a CMOS transistor according to the invention;

FIG. 3 is a side cross-sectional view of a CMOS transistor according to the invention;

FIG. 4 is a top view of a drain-extended CMOS transistor according to the invention; and

FIG. 5 is a side cross-sectional view of a drain-extended CMOS transistor according to the invention.

### DETAILED DESCRIPTION OF EXAMPLE EMBODIMENTS

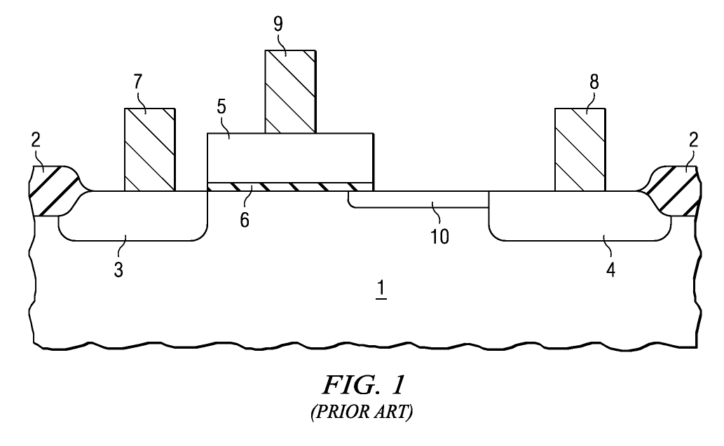

FIG. 1 shows a known CMOS transistor. A substrate 1 is doped at two regions near its surface by diffusing or ion implanting impurities in these regions. This results in two regions that both have an excess of electrons in the case of an n-channel transistor, or an excess of holes in the case of a p-channel transistor. The first doped region forms the source 3 and the second doped region forms the drain 4. The contact areas between the doped regions forming the source 3 and drain 4, respectively, and the substrate form pn junctions (if the doped regions are n-type, the substrate 1 will be p-type, and vice versa).

A gate electrode 5 is arranged on the substrate 1 between the doped regions forming the source 3 and drain 4. The gate electrode 5 is provided on top of a dielectric layer 6, which can be a thin layer of, for example, silicon dioxide or oxinitride. The gate electrode 5 is conducting and made from a polysilicon material, although it could also be made from a metal. Each of the gate 5, source 3 and drain 4 is provided with an ohmic contact: a gate contact 9, a source contact 7 and a drain contact 8, respectively. The gate contact 9 is arranged on top of the gate electrode 5. The source contact 7 and the drain contact 8 are each arranged on top of the source region 3 and the drain region 4, respectively.

A LOCOS oxide, or shallow trench isolation (STI), layer 2 is provided on the substrate 1 around the active area of the transistor, which comprises the gate 5, source 3 and drain 4, so as to insulate the transistor from an adjacent transistor (not shown) when the transistors are incorporated into an integrated circuit.

It can be seen from FIG. 1 that the effective length of the drain region 4 is greater than that of the source region 3; i.e., the distance between the drain contact 8 and the gate contact 9 is greater than the distance between the source contact 7 and the gate contact 9. This is achieved by providing a higher ohmic region than the drain region 4 adjacent to the drain region 4, such that it is arranged between the drain region 4 and the gate electrode 5. The higher ohmic region forms a drain extension 10, because it increases the effective length of the drain region 4. Hence, the transistor is known as a drain-extended MOS transistor. The drain extension 10 contains a lower dopant concentration than the drain region 4. Because of the presence of the drain extension 10, the drain-to-source breakdown voltage is increased, by reducing the electric field under the gate 5 at the drain end of the transistor. Thus, the transistor can operate at much higher drain voltages (15V or more) than a CMOS transistor not having a drain extension, without significant loss of performance. Furthermore, this type of transistor can be made without any modification to standard processing techniques.

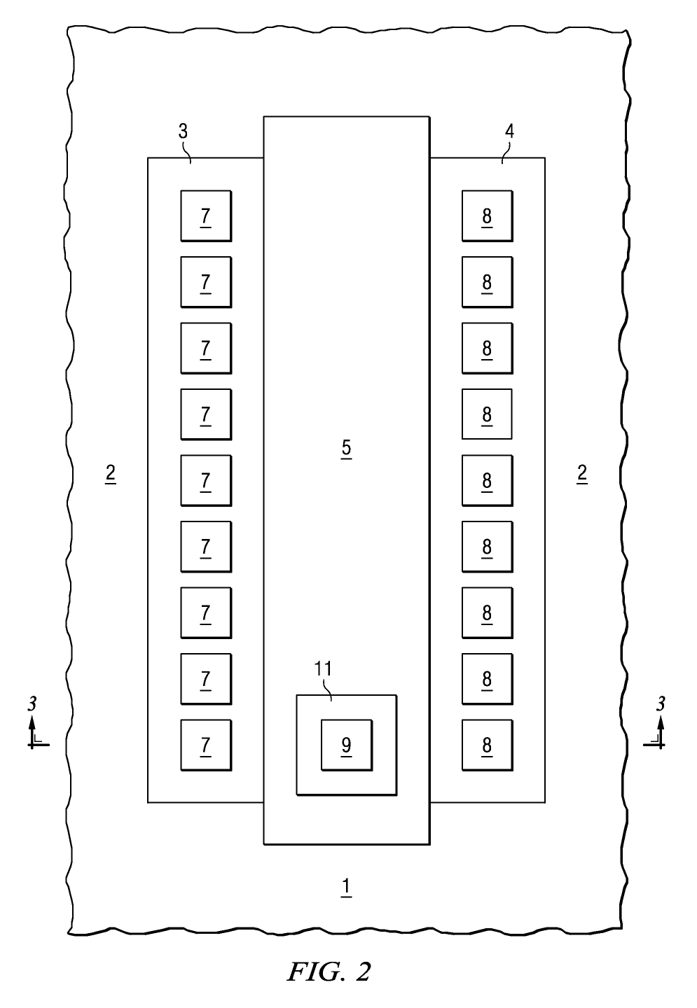

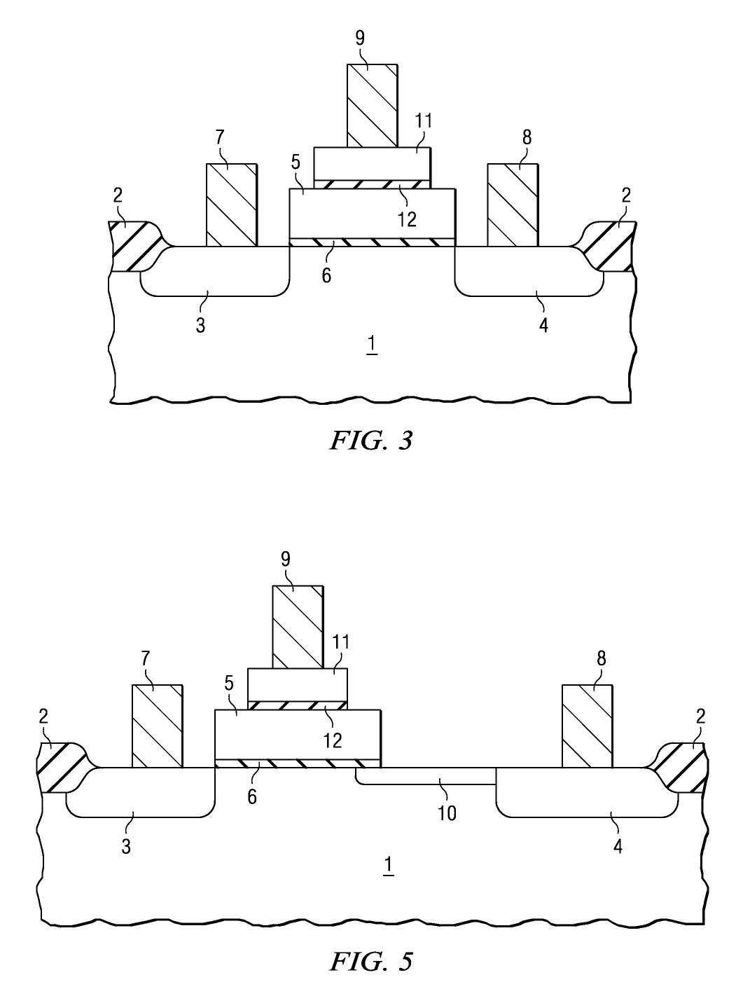

A CMOS transistor according to a first embodiment of the invention, that can be made according to standard CMOS fabrication processes and that can withstand higher gate voltages, is described below with reference to FIGS. 2 and 3.

The transistor comprises a substrate 1, with two doped regions provided in the surface of the substrate 1, formed by known methods such as ion implantation or diffusion. The doped regions both have an excess of electrons or holes, depending on whether the transistor is to be n-channel or p-channel, respectively, and form a source region 3 and a drain region 4. Unlike the known CMOS transistor structure described above, the drain region 4 has substantially the same length as the source region 3 and is not provided with a drain extension.

A polysilicon gate electrode 5 is provided on top of the substrate 1 in between the source region 3 and the drain region 4 and a thin dielectric layer 6 separates the gate electrode 5 from the top surface of the substrate. The gate electrode 5 could also be made from metal and the dielectric layer 6 can be made from any suitable insulating material, for example an oxide of silicon. As with the known CMOS structure, an insulating LOCOS region 2 is provided on the top surface of the substrate 1, outside of the active region of the transistor; i.e., outside of the source region 3, drain region 4 and gate electrode 5.

One or more source contacts 7 and drain contacts 8 are arranged on top of the source region 3 and the drain region 4, respectively. At least one gate contact 9 is also provided on top of the gate electrode 5. However, the gate contact 9 is separated from the gate electrode 5 by a capacitor 11, such that the gate contact 9 is attached to the top surface of the capacitor 11. A thin insulating layer 12, for example nitride or oxide, separates the capacitor 11 from the gate electrode 5. The capacitor 11 may be made of a polysilicon material or TiN.

Because of the provision of the capacitor 11 on top of the gate electrode 5, the gate electrode 5 and the capacitor 11 form a stack. When a voltage is applied to the gate electrode 5 at the gate contact 9, the applied voltage will be dropped across the whole stack, which includes the gate electrode 5 and the capacitor 11, as well as the dielectric layer 6 and the nitride layer 12. The smaller the surface area of the capacitor 11 relative to that of the gate electrode 5, the higher will be the voltage drop over the capacitor 11. Furthermore, the voltage drop across the capacitor 11 can be further increased by decreasing the density of the capacitor 11.

The relative dimensions of the gate electrode 5 and capacitor 11 can thus be chosen to fulfill the requirements of the supply voltage applied to the gate contact 9 of the CMOS transistor. While the voltage at the gate electrode is limited by the gate oxide thickness, the total voltage applied to the stack can be tuned according to the following equation:

Vtotal=Vcmos(1+(Cox*Acmos/Ccap*Acap));

wherein Vtotal=voltage at the total gate stack (where the gate stack includes the gate electrode 5 and the capacitor 11); Vcmos=polysilicon gate voltage; Cox=the capacitance density of a conventional CMOS transistor; Acmos=gate area; Ccap=additional capacitor density; and Acap=additional capacitor area.

There is a maximum limit for the area of the capacitor 11, as it cannot be larger than that of the polysilicon gate 5 below it. Theoretically, Vtotal will therefore be at least 2*Vcmos, as the capacitor density will generally be smaller than the MOS capacitance. The allowable supply voltage across the whole stack can be further increased by reducing the capacitor area. The area and density of the capacitor 11 can thus be chosen such that the voltage drop over the capacitor 11 is maximized. This means that a higher voltage can be applied to the gate 5 without damaging the gate 5. Furthermore, this CMOS structure can be produced without any alteration to existing process techniques. Thus, production is cost-effective and existing design libraries can be used if a polysilicon-polysilicon capacitor is available.

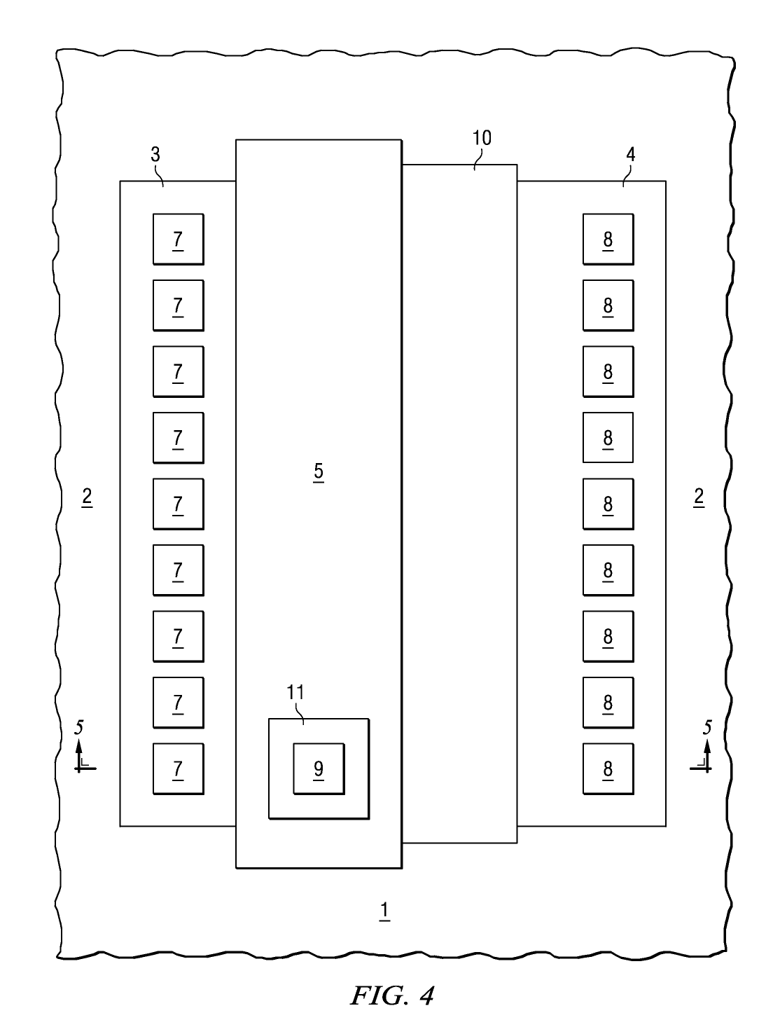

A second embodiment of a CMOS transistor is shown in FIGS. 4 and 5, which also has a substrate 1 with two doped regions close to the surface of the substrate 1, which form a source 3 and a drain 4. In this embodiment, the transistor is a drain-extended CMOS transistor, so that the effective length of the drain 4 (i.e., the dimension of the drain extending towards the source 3) is extended and the length of the drain 4 is greater than that of the source 3. The transistor of this embodiment is also produced by standard CMOS processing techniques.

A polysilicon gate electrode 5 is positioned on the substrate 1 between the source 3 and the drain 4, and a thin dielectric layer 6 separates the gate electrode 5 from the substrate 1. This structure is thus almost the same as that of the first embodiment, apart from that the length of the drain region 4 is extended by a higher ohmic region than the drain region 4 itself, which forms a drain extension 10. The drain extension 10 is formed by doping the surface of the substrate 1 adjacent to the drain 4, in the region between the drain 4 and the gate 5, so that the drain extension 10 has a higher dopant concentration than the drain 4.

A polysilicon capacitor 11 is arranged on top of the gate electrode 5 and is separated from the gate electrode 5 by a thin nitride layer 12. Again, the gate 5, source 3 and drain 4 are insulated by a LOCOS oxide layer 2 provided on the top surface of the substrate 1 outside the active area of the transistor. The LOCOS layer 2 insulates the transistor from adjacent transistors when it is incorporated in a larger integrated circuit. Source contact 7 and drain contact 8 are attached to the top surface of the substrate 1 on top of the source 3 and drain 4 regions, respectively. Gate contact 9 is attached to the top surface of the capacitor 11. The presence of the drain extension 10 means that the distance between the drain contact 8 and the gate contact 9 is greater than the distance between the source contact 7 and the gate contact 9.

In operation of the transistor of FIGS. 4 and 5, as with the first embodiment transistor, described earlier, when a gate voltage is applied to the gate contact 9, the applied voltage will be dropped across the gate electrode 5 and the capacitor 11. If the surface area of the capacitor 11 is made large in comparison with the surface area of the gate electrode 5, the voltage dropped across the capacitor 11 will be maximized, according to the above equation. When the voltage drop over the capacitor 11 is maximized, this means that the gate 5 will “see” a much lower applied voltage, and thus a higher voltage can be applied to the gate 5.

Also, because the drain region 4 is extended, due to the presence of the drain extension 10, which has the effect of lengthening of the drain 4 itself, the drain 4 will “see” a reduced gate-drain voltage. Therefore, it is also possible to apply a high voltage to the drain 4 and it will be able to deal with a high supply voltage without a degradation of performance. Thus, both the gate and drain can be subjected to high applied voltages of about 15V without damaging the performance of the transistor and without process modification.

Although the invention has been described with reference to details of specific representative example embodiments, it is not limited to such embodiments and no doubt further embodiments and alternatives will occur to the skilled person that lie within the scope of the claimed invention.

What is claimed is:

1. A CMOS transistor, comprising:
a substrate having source and drain regions;
a gate electrode arranged on the substrate between the source and drain regions; and
a capacitor provided on the gate electrode such that a voltage applied to the gate electrode is dropped across a stack including the gate electrode and the capacitor.

2. The transistor of claim 1, wherein the relative dimensions of the gate electrode and the capacitor are configured so that the voltage dropped across the capacitor is maximized.

3. The transistor of claim 1, further comprising a drain extension configured to extend the effective length of the drain region.

4. A transistor according to claim 3, wherein the drain extension has a lower dopant concentration than the drain region.

5. A transistor according to claim 4, further comprising a drain contact, a source contact and a gate contact; wherein the drain region and the drain extension are configured such that a distance between a drain contact and a gate contact is greater than a distance between a source contact and the gate contact.
